(19) United States
(12) Patent Application Publication
(10) Pub. No.: US 2022/0399192 A1
(43) Pub. Date: Dec. 15, 2022

(54) SUBSTRATE PROCESSING DEVICE HAVING HEAT HOLE

(71) Applicant: HANWHA CORPORATION, Seoul (KR)

(72) Inventors: Su Woong KIM, Seoul (KR); Dong Won SEO, Gyeonggi-do (KR); Jae Wook CHOI, Gyeonggi-do (KR); Sang Bo KIM, Seoul (KR); Sang Yoon MOON, Gyeonggi-do (KR); Han Young KONG, Seoul (KR); Seung Dae CHOI, Gyeonggi-do (KR); Baek Ju LEE, Gyeonggi-do (KR); Jae Soon HWANG, Gyeonggi-do (KR)

(21) Appl. No.: 17/775,427

(22) PCT Filed: Nov. 22, 2019
(86) PCT No.: PCT/KR2019/016205

§ 371 Date: May 9, 2022

Related U.S. Application Data
(63) Continuation of application No. PCT/KR2019/016205, filed on Nov. 22, 2019.

(30) Foreign Application Priority Data
Nov. 7, 2019 (KR) 10-2019-0141368

(51) Int. Cl. H01J 37/32; H05K 3/00; C23C 16/455; C23C 16/458

(52) U.S. Cl. CPC H01J 37/32724; H05K 3/0097; H01J 37/321; C23C 16/45536; C23C 16/4584; C23C 16/4586; H05K 2203/1509; H05K 2203/0165; H05K 2203/095

(57) ABSTRACT

A substrate processing device according to an embodiment of the present invention includes a disk part disposed in a chamber in which a heating means is provided, and a pocket part installed on one surface of the disk part and on which a substrate is seated. A heat hole through which heat generated by the heating means passes may be formed on an installation surface of the disk part on which the pocket part is installed, or a gear hole through which the heat of the heating means passes may be formed in a pocket gear facing the disk part.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2019/016205, filed Nov. 22, 2019, which claims priority to the benefit of Korean Patent Application No. 10-2019-0141368 filed in the Korean Intellectual Property Office on Nov. 7, 2019, the entire contents of which are incorporated herein by reference.

### BACKGROUND

### 1. Technical Field

The present disclosure relates to a substrate processing device configured to deposit a thin membrane on a substrate or to clean or etch the substrate.

### 2. Background Art

A plurality of substrates may be arranged on one plate to quickly process a plurality of substrates.

With the plate on which the plurality of substrates, thin membrane depositing, etching, etc. on the substrate in a chamber may be performed with respect to the plurality of substrates several times.

However, since a diffusion range or a distribution range of a raw material present in the chamber, and the temperature of the substrate is not uniform, nonuniformity of a processing state of each substrate arranged on the plate easily occurs. Generally, the raw material is concentrated on a center region of the plate, so the thickness of the thin membrane of a substrate region adjacent to the center portion of the plate may be thicker than the thickness of the thin membrane of a substrate region adjacent to an edge of the plate.

Due to the nonuniformity in the thickness of the thin membrane, deviation of the electrical characteristics of the device fabricated on a single substrate is increased, and the yield is reduced.

Korean Patent No. 1150698 disclosed a plurality of susceptors that is transportable a substrate while loading the substrate on a disk part. However, it is difficult to solve the processing uniformity for the substrate.

### SUMMARY

Accordingly, the present disclosure has been made keeping in mind the above problem occurring in the related art, and an objective of the present disclosure is intended to provide a substrate processing device configured to uniformly process a plurality of substrates at the same time.

The technical problems achieved by the present disclosure are not limited to the technical problem described above, and the following description the present disclosure will allow those skilled in the art to more clearly understand other technical problems not described.

A substrate processing device of the present disclosure includes: a disk part disposed in a chamber in which a heating means is provided; and a pocket part provided on a first surface of the disk part and on which a substrate is loaded, wherein a pocket part-installed surface of the disk part may have a heat hole through which heat generated by the heating means passes, or a pocket gear facing the disk part may have a gear hole through which the heat of the heating means passes.

According to the present disclosure, the substrate processing device is configured to use the heat hole formed in the disk part, so that heat transfer efficiency of the pocket part receiving heat generated by the heating means of the chamber and transmitting the heat to the substrate can be improved.

The substrate processing device of the present disclosure is configured to adjust an open area, etc. of the heat hole by using the end cap or the pocket gear, so that the heat transfer efficiency of the pocket part can be controlled in a desired direction.

In the processing such as depositing, etching, etc. using plasma, the pocket part to which the substrate is loaded needs to be electrically connected to the outside space of the chamber.

According to the present disclosure, in order to perform uniform plasma processing on a surface of the substrate, the pocket part can be rotated with respect to the disk part, and a method for electrically connecting the pocket part rotated with respect to the disk part to the ground terminal outside the chamber can be provided.

### BRIEF DESCRIPTION OF THE DRAWINGS

FIG. 1 is a schematic view showing a substrate processing device of the present disclosure.

FIG. 2 is a perspective view showing a disk part of the present disclosure.

FIG. 3 is a perspective view showing the disk part according to a comparative embodiment.

FIGS. 4 to 6 are schematic views showing a heat hole of the present disclosure.

FIG. 7 is a schematic view showing the disk part to which a pocket gear is installed.

FIG. 8 is a perspective view showing the pocket gear of the present disclosure.

FIG. 9 is schematic views showing the pocket gear of the present disclosure.

FIG. 10 is another schematic view showing the substrate processing device of the present disclosure.

FIG. 11 is a perspective view showing a first electric channel according to a first embodiment.

FIG. 12 is a plan view showing the first electric channel according to another first embodiment.

FIG. 13 is a schematic view showing a fixing member.

FIG. 14 is a perspective view showing the first electric channel according to a second embodiment.

FIG. 15 is a plan view showing a state in which a brush of the present disclosure is installed in a fixing groove.

FIG. 16 is a perspective view showing the first electric channel according to a third embodiment.

FIG. 17 is a plan view showing the first electric channel according to another third embodiment.

FIG. 18 is a schematic view showing the brush of the present disclosure.

FIG. 19 is a perspective view showing a bearing.

FIG. 20 is a sectional view showing the bearing.

FIG. 21 is a sectional view showing a state in which a coupling means and the pocket gear are installed in the bearing.

FIG. 22 is an exploded-perspective view showing the bearing.

FIG. 23 is a schematic view showing the first electric channel according to a fourth embodiment.

FIG. 24 is a schematic view showing a surface cut out along line A-A′ in FIG. 23.

FIG. 25 is a schematic view showing a lower surface of a disk part.

FIG. 26 is another schematic view showing the lower surface of the disk part.

FIGS. 27 and 28 are another schematic views showing the lower surface of the disk part.

### DETAILED DESCRIPTION

Hereinafter, preferred embodiments of the present disclosure will be described in detail with reference to the accompanying drawings. It should be understood that the shape and size of the elements shown in the drawings may be exaggeratedly drawn convenience of the description. Furthermore, terms specifically defined in consideration of the composition and operation of the present disclosure may vary according to the intentions or practices of users and operators. Definitions of these terms should be made based on the content throughout this specification.

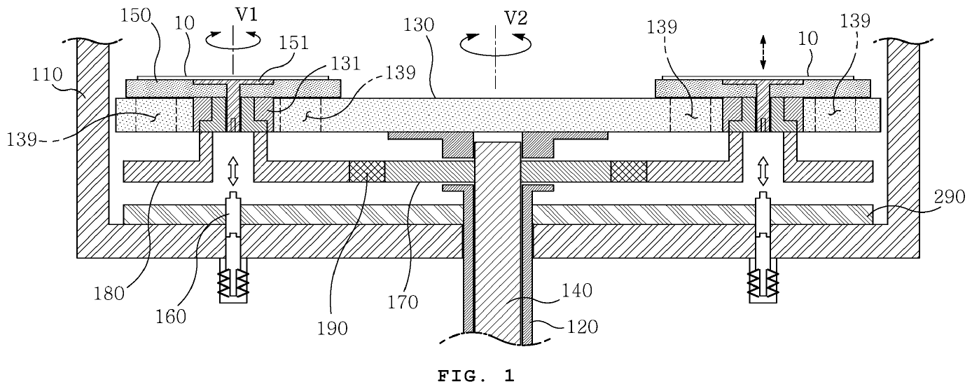

FIG. 1 is a schematic view showing a substrate processing device of the present disclosure.

As shown in FIG. 1, the substrate processing device may include a disk part 130 and a pocket part 150.

The substrate processing device of the present disclosure may include a chamber 110, the disk part 130 installed at a bottom surface of the chamber 110 and supporting at least one substrate 10, and a chamber lid (not shown) covering an upper portion of the chamber 110.

The chamber 110 may perform the substrate processing process by using plasma etc. For example, the chamber 110 may provide a reaction space for an ALD process. Herein, a gas injection part (not shown) may be installed at the chamber lid (not shown), the gas injection part sprays source gas (SG), reactant gas (RG), and purge gas (PG) on different gas spray areas on the disk part 130. Of course, the chamber 110 may be applied to a different substrate processing process other than ALD, CVD, and etching.

The disk part 130 may be fixed to the chamber 110 or rotatably installed at the bottom surface of the chamber 110.

The disk part 130 rotatably installed to the chamber 110 may perform uniform plasma-process on the substrate 10 loaded on the disk part 130. For example, when one type of gas is filled in the entire chamber 110, an entire processed surface of any one specific substrate 10 may be cleaned, deposited, and etched uniformly regardless of a processed area. Furthermore, uniformity of processing (cleaning, depositing, and etching) between a plurality of substrates 10 loaded on the disk part 130 may be improved by rotation of the disk part 130. In order to uniformly perform substrate processing, such as cleaning, depositing, etching, etc., each of the substrates 10 may be needed to be heated uniformly at an appropriate temperature. In order to heat the substrates 10, the disk part 130 may be arranged in the chamber 110 with a heating means 290 such as a heater.

In a case of ALD process, the substrates 10 may be successively exposed by SG, PG, and RG while being moved in a preset order by rotation of the disk part 130. Accordingly, the substrates 10 are successively exposed at SG, PG, and RG by rotation of the disk part 130, whereby a single layered or multiple layered thin membrane generated by an atomic layer deposition (ALD) process may be deposited on the substrates 10.

In the ALD process, SG may be sprayed on one of the substrates 10 facing a SG area, PG may be sprayed on one of the substrates 10 facing a PG gas area, and RG may be sprayed on one of the substrates 10 facing a RG area.

In the ALD process, one specific substrate 10 passes through the SG area, the PG area, and the RG area successively by rotation of the disk part 130 to be deposited with the single-layered or multi-layered thin membrane by the ALD process.

The disk part 130 may be arranged in the chamber 110. The chamber 110 may include a storage space in which the substrate 10, i.e., an object to be process, is stored.

The substrate processing such as the thin membrane deposition process of the substrate 10, the cleaning process of the substrate 10, and the etching process of the substrate 10 may be performed in the chamber 110.

The chemical vapor deposition method (CVD), a physical vapor deposition (PVD), etc. are applied in the thin membrane deposition process, and all the methods require thin membrane row materials such as RG, SG, etc.

In order to improve yield rate, a wafer arranged in the chamber 110, it is preferable that a thin membrane is deposited on an entire area of the substrate 10 such as PCB, etc. at a uniform thickness. Furthermore, in the case in which the plurality of substrates 10 is arranged together in the chamber 110, it is preferable that a thin membrane thickness of one specific substrate 10 and a thin membrane thickness of another substrate 10.

In order to perform the substrate processing including the thin membrane deposition uniformly, a distribution range of the raw material diffused in the chamber 110 may be uniform. However, it is actually difficult to maintain uniformly the distribution of the raw material in the chamber 110, the distribution of the plasma providing energy required to process the substrate 10, etc. Therefore, since the distribution of the raw material in the chamber 110 or the distribution of the plasma is ununiform, it is difficult to perform uniformly the cleaning, depositing, and etching for the substrate 10.

As an example, the raw material or the plasma tends to be concentrated in a center portion of the chamber 110 in a planar manner. Therefore, based on a single layer of the substrate 10, a processing with respect to a portion adjacent to the center portion of the chamber 110 is performed stronger than a processing with respect to a portion adjacent to an edge of the chamber 110. Therefore, in depositing the thin membrane, an ununiform problem in that a first portion of the substrate 10 is deposited thicker than a second portion thereof occurs. The problem may also occur in the cleaning and etching process of the substrate 10.

As another embodiment, when a first substrate 10 and a second substrate 10 are arranged together in the chamber 110, by the uniformity in the distribution of the raw material or the plasma, a thickness of a thin membrane of the first substrate 10 and a thickness of a thin membrane of the second substrate 10 may be different.

The substrate processing device of the present disclosure may be provided to provide a uniform processing state for each area of a single substrate 10 regardless of whether distribution of raw material or distribution of plasma is ununiform. In addition, the substrate processing device of the present disclosure may be provided to make uniform processing states of the plurality of substrates 10 processed at the same time.

The substrate processing device of the present disclosure may use the pocket part 150 so as to process all the plurality of substrates 10 together.

The pocket part 150 may be installed at a first surface of the disk part 130 and may have a plate shape on which the substrate 10 is loaded. A seating groove 138 on which the substrate 10 is loaded may be formed on a first surface of the pocket part 150 facing the substrate 10. The seating groove 138 may be formed in the same shape as a seated portion of the substrate 10 so as to prevent the substrate 10 from being damaged and to ensure the substrate processing such as deposition.

At least one pocket part 150 may be arranged on the disk part 130.

In order to process the plurality of substrates 10 together, the center of each of a plurality of pocket parts 150 provided on the disk part 130 may be different from the center of the chamber 110 in a planar manner. Therefore, a first portion of the pocket part 150 and a first portion of the substrate 10 loaded on the pocket part 150 may be arranged adjacent to the center portion of the chamber 110, and a second portion of the pocket part 150 and a second portion of the substrate 10 loaded on the pocket part 150 may be arranged adjacent to an edge of the chamber 110. Herein, in order to prevent the substrate 10 from being processed ununiformly, a first rotating part and a second rotating part may be used.

The first rotating part may rotate first the pocket part 150. Herein, it may preferable that the pocket part 150 has a circular shape in the planar manner to be suitable to the first rotation.

The first rotation of the pocket part 150 is rotation performed such that the pocket part 150 is rotated on the center of the pocket part 150 in the planar manner as a rotary center, and hereinbelow, the first rotation of the pocket part 150 is referred to as rotation of the pocket part 150 on its axis. The first rotation of the pocket part 150 may be rotation performed such that the pocket part 150 is rotated more than 360 degrees with respect to the chamber 110.

The second rotating part may secondarily rotate the pocket part 150.

Compared to the rotation of the pocket part 150, the second rotary of the pocket part 150 may be rotation performed such that the pocket part 150 is rotated on an imaginary shaft provided outside the pocket part 150 as a rotary center. Herein, it is preferable that the imaginary shaft is provided at the center of the chamber 110 or the center of the disk part 130. In the above case, the second rotation of the pocket part 150 may be referred to as a revolution performed such that the pocket part 150 is revolved around an imaginary shaft.

As an example, in order to revolve the pocket part 150, the second rotating part may revolve the disk part 130 in which the plurality of pocket parts 150 is installed may around the center of the disk part 130.

According to the rotation of the pocket part 150, a first area facing the center of the chamber 110 in the substrate 10 loaded on the pocket part 150 is not fixed and is changed all times, so that the entire area of the substrate 10 may be processed uniformly. As an example, according to the first rotating part, both the first and second portions of the substrate 10 may be deposited with uniform thickness of thin membranes, and the substrate 10 may be deposited with uniform thickness of thin membrane without division of the area of the substrate. In the case of cleaning or etching, the entire area of the substrate 10 may be cleaned or etched by a uniform depth.

Meanwhile, when the first substrate 10 is arranged in a first location in the chamber 110 and the second substrate 10 is arranged in a second location in the chamber 110, a raw material density or plasma density at the first location may be different from a raw material density or plasma density at the second location. Accordingly, the thickness of the thin membrane of the first substrate 10 and the thickness of the thin membrane of the second substrate 10 may be different from each other. In order to form the thickness of the thin membrane deposited on the first substrate 10 to be same as the thickness of the thin membrane deposited on the second substrate 10, the second rotating part may rotate the disk part 130 to revolve the pocket part 150.

As an example, when the first substrate 10 and the second substrate 10 pass through the first location and the second substrate 10 alternately by the second rotating part, the thickness of the thin membrane of the first substrate 10 and the thickness of the thin membrane of the second substrate 10 may be uniform.

According to the present disclosure, processing uniformity of the single substrate 10 is improved by the first rotating part, and processing uniformity between the plurality of substrates 10 may be improved by the second rotating part. Therefore, the entire yield of the substrate 10 may be significantly improved by rotation and revolution of the pocket part 150.

It is preferable that the first rotating part and the second rotating part are independently operated. Because, when the first rotating part rotates first the pocket part 150 at a first velocity V1 and the second rotating part moves secondarily the disk part 130 at a second velocity V2, in order to make uniform thickness of thin membranes, it is preferable that V1 and V2 is adjusted independently.

The substrate processing device of the present disclosure may include a controller separately controlling the first rotating part and the second rotating part from each other. A user checks a processing result of the substrate 10 and then separately adjust the first velocity V1 of the first rotating part and the second velocity V2 of the second rotating part by using the controller retrospectively.

As a comparative example, a state where the first rotating part and the second rotating part are linked together. In the above case, the first velocity V1 of the pocket part 150 and the second velocity V2 of the disk part 130 may be set in conjunction with each other.

When the first velocity V1 is adjusted to a1 to improve the processing uniformity of the single substrate 10, the second velocity V2 may be forcibly determined as b1. In the above case, when the processing uniformity between the substrates 10 is satisfied, there is no problem, and even when the processing uniformity between the substrates 10 are unsatisfied, inevitably, the second velocity V2 should be determined as b1. Therefore, there may be a problem in that the processing uniformity of the single substrate 10 is satisfied, but the processing uniformity between the plurality of substrates 10 is unsatisfied.

On the other hand, when the second velocity V2 is adjusted to b2 to improve the processing uniformity between the plurality of substrates 10, the first velocity V1 may be forcibly determined as a2. In the above case, the processing uniformity between the substrates 10 may be satisfied, but the processing uniformity of the single substrate 10 may not be satisfied to the preset value.

However, according to the substrate processing device of the present disclosure, since the first rotating part and the second rotating part are driven independently, the first velocity V1 of the pocket part 150 may be adjusted to a1 and the second velocity V2 of the disk part 130 may be adjusted to b2. Therefore, according to the present disclosure, the processing uniformity of the single substrate 10 may satisfy the preset value and simultaneously the processing uniformity between the plurality of substrates 10 may satisfy the preset value.

Meanwhile, when the first rotating part rotating the pocket part 150 on its axis is fixed to the chamber 110, rotation of the disk part 130 and revolution of the pocket part 150 related to the rotation of the disk part 130 may be limited by the first rotating part.

In order to allow the second rotating part to efficiently move the disk part 130, the first rotating part may rotate the pocket part 150 while being moved together with the disk part 130.

As an example, when the disk part 130 performs a linear reciprocating motion, the first rotating part may also perform a linear reciprocating motion together with the disk part 130. For example, when the disk part 130 performs a rotating motion, the first rotating part may also perform a rotating motion together with the disk part 130. Specifically, a relative velocity between the disk part 130 and the first rotating part may converge to 0.

The first rotating part may include a first motor rotating the pocket part 150, and a link means located between the first motor and the pocket part 150 and transmitting a rotary power of the first motor to the pocket part 150.

As an example, the link means may include a pocket gear 180 connected to the pocket part 150, a main gear 170 linked to the pocket gear 180, and the first motor rotating the main gear 170. When the main gear 170 is rotated together with a first shaft 140, the first motor may rotate the first shaft 140. In order to improve the processing uniformity of the single substrate 10, it is preferable that the first shaft 140 is formed on a center portion of the pocket part 150.

When the first motor is rotated, the first shaft 140 connected to a motor shaft of the first motor may be rotated. The main gear 170 is rotated by rotation of the first shaft 140, and the pocket gear 180 linked to the main gear 170 may be rotated. When the pocket gear 180 is rotated, the pocket part 150 may be rotated (first rotation).

When a motor shaft of the first motor is rotated, regardless of whether the disk part 130 is rotated, the pocket part 150 may be rotated with respect to the disk part 130 while the first shaft 140 connected to the motor shaft of the first motor is rotated.

In order to rotate the pocket part 150 and not limit revolution of the pocket part 150, the first motor rotating the pocket part 150 may be revolved around a second shaft 120 together with the pocket part 150.

For example, the first shaft 140 and the second shaft 120 are arranged coaxially, the first motor may be fixed at one location.

For example, the second shaft 120 may have a hollow pipe shape. Herein, the first shaft 140 may be rotatably inserted into a hollow portion of the second shaft 120. According to the above description, only the second shaft 120 may pass through the chamber 110 externally. Of course, an example in which the first shaft 140 is formed in a hollow pipe shape and the second shaft 120 is inserted into the hollow portion of the first shaft 140 may be possible.

The pocket part 150 and the disk part 130 may be rotated different rotary directions and velocities by the first motor and a second motor individually controlled by the controller.

A lift portion 151 may be provided at a middle portion of the pocket part 150 to raise and lower the substrate 10. When the lift portion 151 is moved upward, the substrate 10 may be spaced apart from the seating groove 138 of the pocket part 150, and when the lift portion 151 is moved downward, the substrate 10 may be loaded on the seating groove 138.

A thin membrane may be deposited on the substrate 10 loaded on a bottom surface of the seating groove 138, and a part of the thin membrane may be deposited on an edge of the pocket part 150 with a greater diameter than a diameter of the substrate 10. As described above, the substrate 10 and the pocket part 150 may be brought into partially attached to each other by the thin membrane, and the attached state may be released by the lift portion 151. Herein, the substrate 10 may be easily damaged by the pressure of the lift applied to release the attached state. Furthermore, in a process of releasing the attached state by upward and downward movements of the lift portion 151, the substrate 10 may be inclined and separated from the lift portion 151.

In order to prevent the substrate 10 from being damaged, the lift portion 151 of the present disclosure may have a particular structure.

The lift portion 151 may include a plate portion extended in a flat manner in parallel with the bottom surface of the seating groove 138 of the pocket part 150 so that pressure applied to the substrate 10 is distributed by the process to release the attached state. The plate portion is in surface-contact with the substrate 10, so that the plate portion may uniformly distribute the pressure applied to the substrate 10 and may prevent the substrate 10 from being inclined in the upward and downward movement process.

In order to protect the substrate 10, it is preferable that the plate portion is maintained in parallel with the bottom surface of the seating groove 138 of the pocket part 150. The lift portion 151 may include an extension portion that is extended downward from a center portion of the plate portion, so that the plate portion is arranged in parallel with the bottom surface of the seating groove 138. An extended direction of the extension portion may be the same as the upward and downward directions of the plate portion. The extension portion may be provided by passing through the first through hole 134 formed in the disk part 130. Herein, the first through hole 134 may be extended from an upper surface to a lower surface of the disk part 130.

A side surface of the lift portion 151 may be formed in a ‘T’ shape by the plate portion and the extension portion. Herein, the extension portion may be slidingly moved upward or downward along the first through hole 134 of the disk part 130. The extension portion guided by the first through hole 134 is prevented from being inclined differently from the upward direction, and the plate portion connected to the extension portion may also be maintained in a state parallel to the bottom surface of the seating groove 138 of the pocket part 150.

The chamber 110 may include the lift drive part 160 pushing up the extension portion or pulling down the extension portion.

The first rotating part may be arranged to face the lower surface of the disk part 130. Herein, when the disk part 130 or the pocket part 150 are moved, the lift drive part 160 may be maintained in a lowered state to escape from the first rotating part. Herein, the lift portion 151 may be lowered by the own weight. When the disk part 130 and the pocket part 150 stop, the lift drive part 160 is moved upward, thereby pushing the extension portion of the lift portion 151 exposed from the lower surface of the disk part 130.

The pocket part 150 may be installed to face the first through hole 134 of the disk part 130. The pocket part 150 may be connected to the pocket gear 180 through the first through hole 134 of the disk part 130. Herein, a bearing 131 may be disposed between the pocket gear 180 and the first through hole 134 or between the pocket part 150 and the first through hole 134 to allow rotation of the pocket gear 180 or the pocket part 150. The bearing 131 is an element connected to the pocket part 150 and may be rotatably supported by the disk part 130. As an example, the bearing 131 may form the first bearing 140 that is the center of the rotation of the pocket part 150, and include a bearing. The bearing may be rotatably supported by the disk part 130.

The substrate processing device may include the heating means 290. The heating means 290 may be installed in the chamber 110 and may heat the substrates 10 to a preset temperature. The preset temperature may be determined as a temperature where the substrate processing, such as thin membrane deposition, is efficiently performed. The heating means 290 may be installed between the disk part 130 and a lower surface of the chamber 110. When the pocket part 150 is installed on the first surface of the disk part 130, the heating means 290 may include a heater, etc. installed on a second surface of the disk part 130 in the chamber 110.

The pocket part 150 may serve to be supplied with heat from the heating means 290 installed below the disk part 130 and transmit the heat to the substrate 10.

However, the disk part 130 arranged between the heating means 290 and the substrate 10 may block the heating means 290 off from the pocket part 150. The first through hole 134 formed in the disk part 130 is provided to install both the bearing 131 and the lift portion 151. Therefore, when the bearing 131 and the lift portion are installed, the first through hole 134 may be closed. Therefore, the heating means 290 may be completely blocked from the pocket part 150 by the disk part 130.

In order to transmit heat of the heating means 290 to the pocket part 150 through the disk part 130, an installation surface of the disk part 130 on which the pocket part 150 is installed may have a separate heat hole 139 through which the heat generated by the heating means 290 passes. The heat generated by the heating means 290 such as the heater, etc. may be directly transmitted to the pocket part 150 while passing through the heat hole 139.

When the pocket part 150 includes a plurality of pocket parts provided at the disk part 130, the heat hole 139 may be formed at each location facing the plurality of the pocket parts 150. Herein, the heating means 290 may be installed at a location facing the heat hole 139. The heating means 290 and the disk part 130 may be configured to be relatively moved to each other so that a plurality of heat holes 139 alternately passes through the location facing a particular portion of the heating means 290.

As an example, while the heating means 290 is fixed to the chamber 110, the heat hole 139 may be revolved together with the pocket part 150. Even when the heat of the heating means 290 is different for each portion, the plurality of pocket parts 150 may be uniformly heated by the revolved heat hole 139. The heating means 290 may be rotated on the second shaft 120 that is the center of rotation of the disk part 130, so that uniform heating of the plurality of pocket parts 150 is performed more securely.

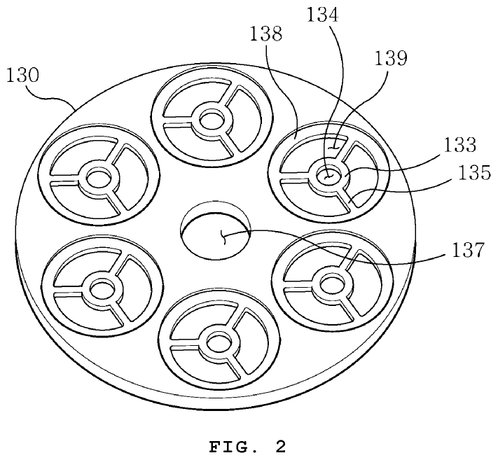

FIG. 2 is a perspective view showing the disk part 130 of the present disclosure.

When the seating groove 138 is formed on the first surface of the disk part 130 so that the pocket part 150 is seated on the seating groove 138, the heat hole 139 may be formed in the center portion of the bottom surface of the seating groove 138. In order to support the pocket part 150, a diameter of the heat hole 139 may be formed smaller than a diameter of the pocket part 150.

Due to a difference in the diameters between the heat hole 139 and the pocket part 150, a center portion of the pocket part 150 seated in the seating groove 138 faces the heat hole 139, and an edge of the pocket part 150 seated in the seating groove 138 may be rotatably supported by an edge of the bottom surface of the seating groove 138.

When the pocket part 150 is installed in the disk part 130 to be rotatable, the bearing 131 such as the bearing, etc. may be supported by the disk part 130. However, with the heat hole 139 having the diameter larger than a diameter of the bearing 131, the bearing 131 may be an unrealistic state in which part the bearing 131 floats in the center portion of the heat hole 139.

In order to install the bearing 131, the substrate processing device of the present disclosure may include an installation portion 133 provided at the center portion of the heat hole 139, and a connection portion 135 crossing the heat hole 139 to connect the installation portion 133 to the disk part 130.

The bearing 131 that is the center of rotation of the pocket part 150 may be installed in the installation portion 133. As an example, the installation portion 133 may have a ring shape with the first through hole 134 into which the bearing 131 is installed. The pocket part 150 may be installed in the disk part 130 to be rotatable on the bearing 131 with respect to the disk part 130.

A plurality of connection portions 135 may be provided to securely support the installation portion 133. The plurality of connection portions 135 may be respectively arranged at different angles around the installation portion 133. Preferably, each of the connection portions 135 may be arranged around the installation portion 133 at equiangular angles.

The heat hole 139 may be divided into a plurality of heat holes 139 by the plurality of connection portions 135. The plurality of connection portions 135 may perform a function of a block plate blocking the heat hole 139 from the pocket part 150. Therefore, each of the connection portions 135 may have a rod shape, so that a blocked area of the heat hole 139 by the connection portions 135 is minimized. The plurality of divided heat holes 139 may have a fan shape by the rod-shaped connection portions 135.

When the lift portion 151 is provided at the center portion of the pocket part 150 to raise and lower the substrate 10, the middle portion of the bearing 131 may have a lift hole 132 through which the lift drive part 160 passes to push up or pull down the lift portion 151.

When the disk part 130 is rotatably provided with respect to the chamber 110, the center portion of the disk part 130 may have a second through hole 137 in which the second shaft 120, etc. is installed.

The disk part 130 may receive the heat of the heating means 290 and uniformly transmit the heat to the substrate 10. A heat shield may be provided at a side surface of the disk part 130 with a small gap between the heat shield and the disk part 130. The heat shield may minimize heat loss through an inner wall of the chamber.

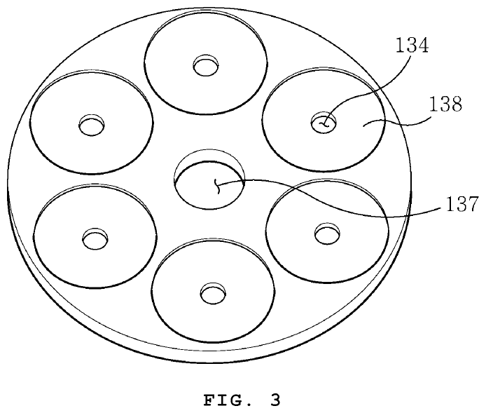

FIG. 3 is a perspective view showing the disk part 130 according to a comparative embodiment.

The disk part 130 of the comparative embodiment in FIG. 3 includes both the first through hole 134 provided to install the bearing 131, and the second through hole 137 provided to install the second bearing 120, and excludes the heat hole 139.

As a result, the bottom surface of the seating groove 138 completely blocks the heating means 290, and heat loss of the heating means 290 with respect to the substrate 10 is increased.

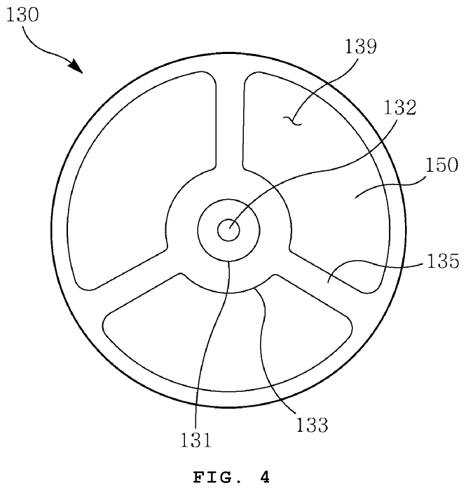

FIGS. 4 to 6 are schematic views showing the heat hole 139 of the present disclosure. FIGS. 4 to 6 show the second surface of the disk part 130 facing the bottom surface of the chamber 110. In other words, FIGS. 4 to 6 show the disk part 130 in a bottom to top direction.

The processing result of the substrate 10 may be changed in response to a state of the substrate 10 heat through the pocket part 150. As the shape such as a size and an angle of the heat hole 139 is adjusted in response to the processing result of the substrate 10, the heat transmitted to the substrate 10 through the pocket part 150 may be adjusted.

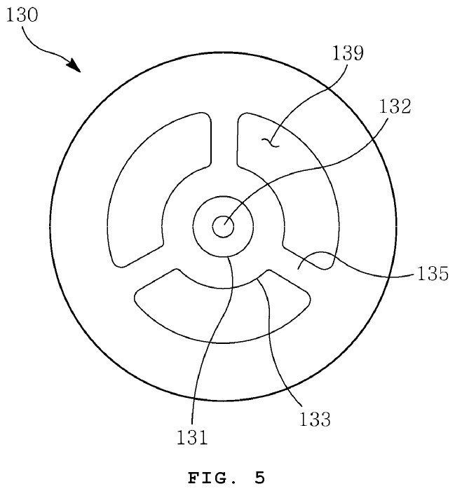

As an example, when the substrate 10 is overheated by a maximum-size heat hole 139 as shown in FIG. 4, the disk part 130 with a small-size heat hole 139 as shown in FIG. 5 is used to prevent overheating of the substrate 10.

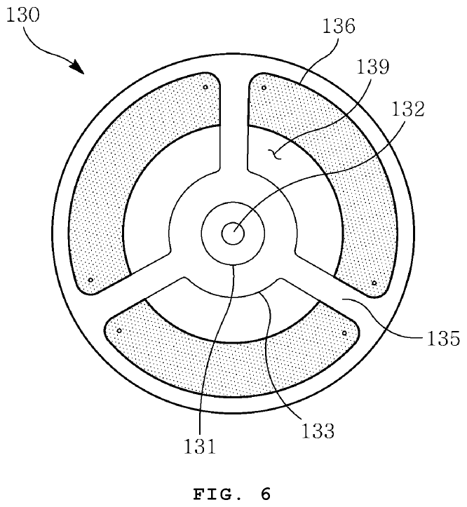

It is difficult to replace the disk part 130 with the different-size heat hole 139 whenever the size of the heat hole 139 is changed. An end cap 136 as shown in FIG. 6 may be provided to adjust the size of the heat hole 139 without replacement of the disk part 130.

The end cap 136 is installed at the second surface of the disk part 130 and may be formed to partially block a part of the heat hole 139. The end cap 136 may adjust an open area of the heat hole 139 exposed toward the second surface of the disk part 130. As an example, the end cap 136 may be removably formed at the second surface of the disk part 130, and may have various sizes.

When the end cap 136 in FIG. 6 blocks the heat hole 139 in FIG. 4, a small-size heat hole 139 may be provided as shown in FIG. 5.

When the size of the heat hole 139 is reduced, it is preferable that the end cap 136 blocks from an outer circumferential edge of the heat hole 139 and then the center portion of the heat hole 139. In the comparative embodiment in which the width of the connection portions 135 is increased to reduce the size of the heat hole 139, the temperature uniformity of the pocket part 150 may be deteriorated.

The heat passing through the gap between the side surface of the disk part 130 and the inner wall of the chamber 110 mainly heats an edge of the substrate 10, the edge of the substrate 10 is easily heated higher than a center portion of the substrate 10. According to the embodiment in which blocking is performed from the edge of the heat hole 139, the center portion of the substrate 10 is securely heated through the pocket part 150, so that the entire area of the substrate 10 may be uniformly heated.

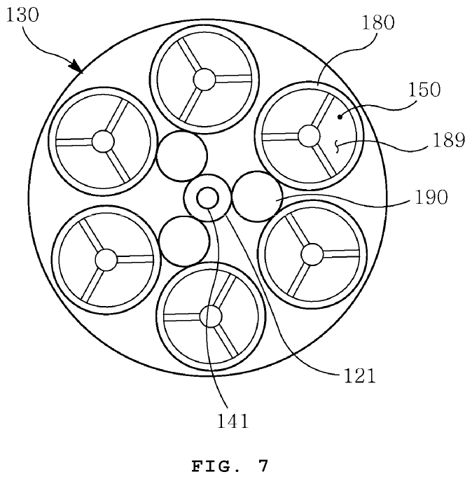

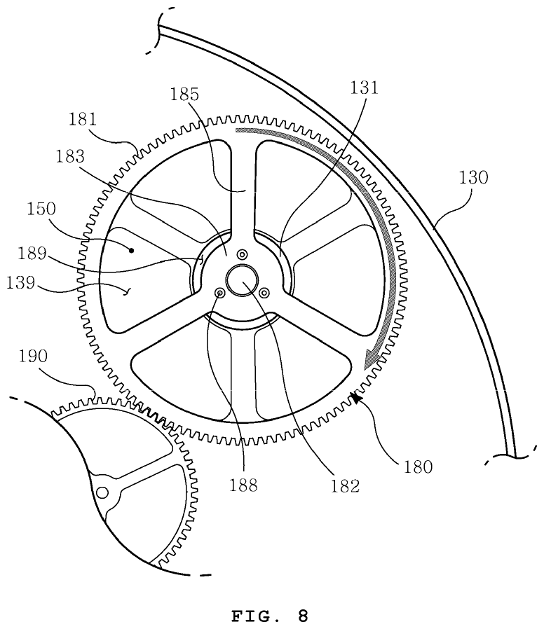

FIG. 7 is a schematic view showing the disk part 130 to which the pocket gear 180 is installed. FIG. 8 is a perspective view showing the pocket gear 180 of the present disclosure. FIGS. 7 and 8 show the disk part 130 or the pocket gear 180 in the bottom to top direction.

The pocket gear 180 or a middle gear 190 shown in FIGS. 7 and 8 may be replaced with a belt, a pulley, etc. that may transmit a rotating force.

The middle portion of the disk part 130 may include a first connection means 141 connected to the first shaft and a second connection means 121 connected to the second shaft.

The substrate processing device of the present disclosure may include the pocket gear 180 installed at the second surface of the disk part 130 and connected to the pocket part 150, a link gear engaged with the pocket gear 180, and a first drive part rotating the link gear.

The first drive part may include the first motor.

The link gear may include a motor shaft gear installed at a motor shaft of the first motor. Alternately, the link gear may include the middle gear 190 disposed between the motor shaft gear and the pocket gear 180.

When the first drive part rotates the link gear, the pocket part 150 may be rotated together with the pocket gear 180 engaged with the link gear. The link gear may be arranged at a different location from the pocket gear 180 in a direction parallel to the disk part 130.

When the pocket part 150 is provided on the first surface of the disk part 130, the pocket gear 180 and the link gear provided at the second surface of the disk part 130 may block the heat hole 139 from the heating means 290.

In order to expose the heat hole 139 to the heating means 290, a portion of the pocket gear 180, which faces the heat hole 139, may have a gear hole 189 through which the heat of the heating means 290 passes. Herein, when a part of the link gear faces the heat hole 139, the pass efficiency of the heat through the gear hole 189 is reduced or it may be difficult to control the heat passing through the heat hole 139. In order to improve the heat pass efficiency or the heat control, it is preferable that the link gear is arranged at a location spaced apart from the heat hole 139 in a planar manner. In other words, the link gear may be arranged at a location deviated from the heat hole 139 and not blocking the heat hole 139.

In order to space the link gear from the heat hole 139, the pocket gear 180 may be formed to have a diameter or a size that may cover the heat hole 139.

The pocket gear 180 may be formed to have the special structure so as to have the gear hole 189.

As an example, the pocket gear 180 may include a ring portion 181 having a ring shape and having teeth engaged with another gear, a center portion 183 removably coupled to the bearing 131, and a connection portion 185 crossing the gear hole 189 to connect the ring portion 181 to the center portion 183. Herein, the ring portion 181 may have a size or a diameter that may cover the entire heat hole 139 formed at the location of the single pocket part 150.

The connection portion 185 divides the gear hole 189 into a plurality of gear holes 189, and each of the gear holes 189 may have a fan shape, and the like.

The pocket gear 180 of the present disclosure is an element rotated together with the pocket part 150 with respect to the heat hole 139. The gear hole 189 formed in the pocket gear 180 may affect the temperature of the substrate 10. Furthermore, the gear hole 189 reduces the total weight of the disk part 130, thereby reducing necessary power required for rotation of the disk part 130 and simultaneously preventing the edge of the disk part 130 from sagging.

When the pocket gear 180 is rotated, the connection portion 185 may periodically block the heat hole 139.

The pocket gear 180 may include a plurality of types of connection portions 185 of which at least one of an installed location, the number, an area, and a shape is different from each other.

The plurality types of pocket gears 180 may be provided to be replaceable to the bearing 131 so as to adjust the amount of the heat passing through the heat hole 139.

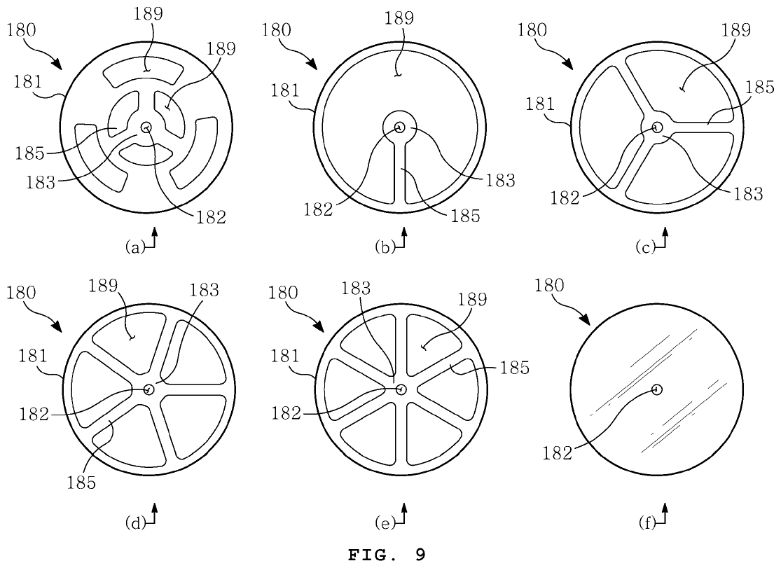

FIG. 9 is schematic view showing the pocket gear 180 of the present disclosure.

The amount of the heat passing through the heat hole 139 may be adjusted by change of the connection portion 185 periodically blocking the heat hole 139 while being rotated.

As an example, as shown in (a) of FIG. 9, when the gear hole 189 is formed at each of outer and inner circumferences of the pocket gear 180, different amounts of heat may be applied to the edge portion and the center portion of the pocket part 150.

As shown in (b) and (e) of FIG. 9, when the number of the connection portions 185 connecting the center portion 183 to the ring portion 181 is increased, the amount of heat passing through the heat hole 139 may be gradually reduced.

When the heating means 290 is a radiant heat source, the pocket gear 180 may include a transparent material such as quartz, as shown in (f) of FIG. 9. Even when the pocket gear 180 is made of a transparent material, it is preferable that the pocket gear 180 has the gear hole 189 so as to reduce the total weight of the disk part 130.

A through hole 182 through which the lift portion 151 passes may be provided at a middle portion of the center portion 183.

A removable-coupling hole 188 is formed in an edge of the center portion 183 to be removably coupled to the edge of the bearing 131. FIG. 8 shows a state in which the removable-coupling hole 188 is mounted to the bearing 131 by a screw.

The lift hole 132 and a through hole 182 may be coaxially arranged, so that the lift portion 151 or the lift drive part 160 is normally operated through the lift hole 132 formed in the installation portion 133 and the through hole 182 formed in the center portion 183.

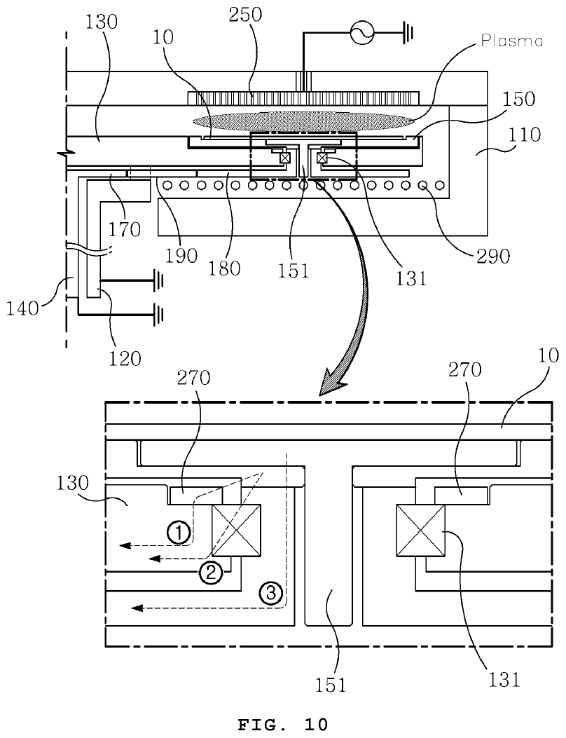

FIG. 10 is another schematic view showing the substrate processing device of the present disclosure.

In the process such as cleaning, depositing, etching, etc., the pocket part 150 on which the substrate 10 is loaded should be electrically connected to the outside space of the chamber 110.

As an example, in the substrate processing using plasma, an upper electrode 250 or an antenna may be provided at an upper portion of the chamber 110. The upper electrode 250 or the antenna may be connected to a high-power high-frequency power supply and to which high-frequency power is applied. Herein, the pocket part 150 needs to be electrically connected to a lower electrode or a ground terminal that induces to generate plasma in the chamber 110 together with high. When necessary, DC power may be applied to the pocket part 150 to cause an electromagnetic force that adsorbs the substrate 10 to the pocket part 150.

However, according to the present disclosure, since the pocket part 150 is rotatably installed to the disk part 130, a separate electrical connection means performing electrical connection between a rotated object and a fixed object should be provided.

The pocket part 150 may be grounded to the ground terminal through at least one of a first electric channel \textcircled{1}, a second electric channel \textcircled{2}, and a third electric channel \textcircled{3} through which electricity communicates.

The first electric channel \textcircled{1} may be an electric channel in which the pocket part 150 is electrically connected to the disk part 130 by using a brush 270 in physically contact with the pocket part 150 and the disk part 130, when the conductive disk part 130 (including the disk part 130 with a conductive pattern) electrically connected to the ground terminal is provided.

The second electric channel \textcircled{2} may be an electric channel in which the pocket part 150 is electrically connected to the disk part 130 by a bearing or a bushing corresponding to the bearing 131, when the conductive disk part 130 electrically connected to the ground terminal is provided.

The third electric channel \textcircled{3} may be an electric channel in which the pocket part 150 is electrically connected to the pocket gear 180 by a bearing when the pocket gear 180 electrically connected to the ground terminal is provided.

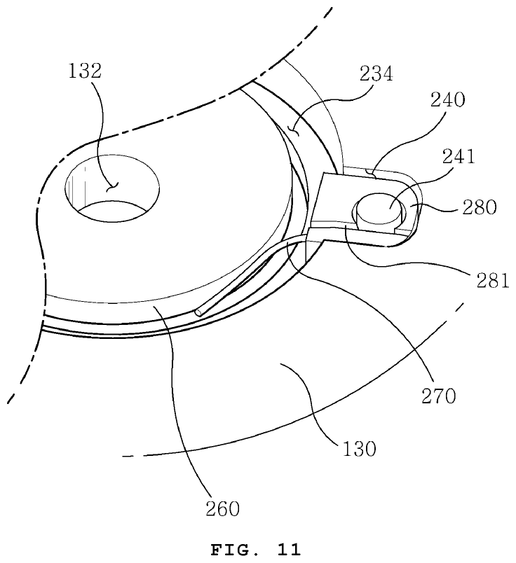

FIG. 11 is a perspective view showing a first electric channel according to a first embodiment.

In the installation portion 133 formed in the center portion of the heat hole 139, the first surface of the installation portion 133 facing the pocket part 150 may have a coupling groove 234 into which a coupling means 260 provided at the pocket part 150 is inserted. The coupling means 260 may be an element rotated together with the pocket part 150, and may be provided separately from the pocket part 150 and then be coupled to the pocket part 150, or may be integrally formed with the pocket part 150. The coupling means 260 may include a rotation shaft rotated together with the pocket part, a pocket, a gear, etc.

A middle portion of a bottom surface of the coupling groove 234 has the first through hole 134. The first through hole 134 has a diameter smaller than a diameter of the coupling groove 234 and into which the bearing 131 is inserted.

The coupling means 260 inserted into the coupling groove 234 may be connected to the bearing 131 to be rotated together with the bearing 131.

As an example, the bearing corresponding to the bearing 131 may include an outer wheel 310 and an inner wheel 330 that are relatively rotated. Herein, the outer wheel 310 may be fixed to the first through hole 134 and the inner wheel 330 may be fixed to the coupling means 260. When the inner wheel 330 is rotated with respect to the outer wheel 310, the pocket part 150 with the coupling means 260 is consequently rotated with respect to the disk part 130 with the first through hole 134.

The diameter of the coupling groove 234 may be larger than a diameter of the coupling means 260. Due to a difference between the diameters, a gap may be provided between an inner wall of the coupling groove 234 and a side surface of the coupling means 260. The brush 270 disposed between the inner wall of the coupling groove 234 and the side surface of the coupling means 260 may be provided by using the gap.

The brush 270 may include a conductive material through which electricity communicates.

A first end of the brush 270 may be fixed to the conductive disk part 130. A second end of the brush 270 may protrude from the inner wall of the coupling groove 234 toward the side surface of the coupling means 260, and be bent in a different direction from the protruding direction thereof, and be configured to be brought into sliding-contact with the side surface of the rotated coupling means 260. On the other hand, the first end of the brush 270 may be fixed to the side surface of the coupling means 260 and be rotated together with the coupling means 260. Herein, the second end of the brush 270 may be brought into sliding-contact with the conductive disk part 130.

The brush 270 may have various shapes based on a wire shape or a plate shape, which may maintain elasticity.

When the brush 270 is separated from the disk part 130 and is freely moved between the coupling means 260 and the inner wall of the coupling groove 234, the coupling means 260 or the pocket part 150 may be damaged, thus a method may be preferably provided to support the brush 270.

As an example, a fixing groove 240 may be formed in a part of the inner wall of the coupling groove 234, the fixing groove 240 is hollowly recessed in a radially direction of the bearing 131. Herein, the substrate processing device may include a fixing member 280 provided in the fixing groove 240. The fixing member 280 may have an insertion groove 281 into which the first end of the brush 270 is inserted. The fixing member 280 may be coupled to the fixing groove 240 by a coupling member 241 such as a screw. The brush 270 of which the first end is inserted in the insertion groove 281 of the fixing member 280 may be consequently fixed to the fixing groove 240 by the fixing member 280 by screw-coupling or forcible-fitted assembling, and welding.

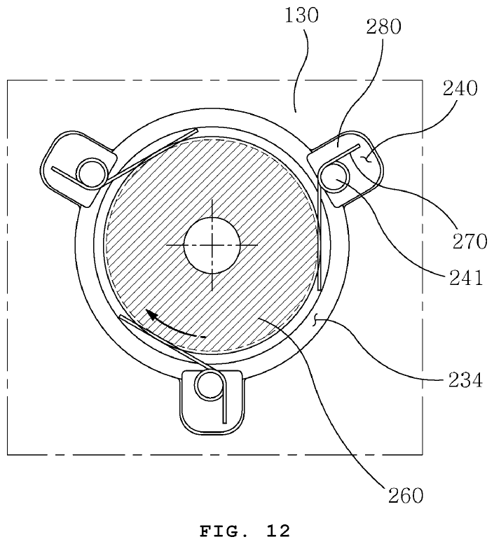

FIG. 12 is a plan view showing the first electric channel according to another first embodiment.

The first end of the brush 270 may be wound on the coupling member 241 coupled to the fixing groove 240, so that the brush 270 is securely fixed to the fixing groove 240. The brush 270 of which the first end is wound on the coupling member 241 may have a shape same as a torsion spring.

The brush 270 of which the first end is fixed to the insertion groove 281 of the fixing member 280 or the coupling member 241 may be elastically in contact with the coupling means 260.

The coupling means 260 rotated together with the pocket part 150 may be electrically connected to the brush 270 while being brought into sliding-contact with the second end of the brush 270. The brush 270 may be electrically connected to the ground terminal or the lower electrode through the disk part 130.

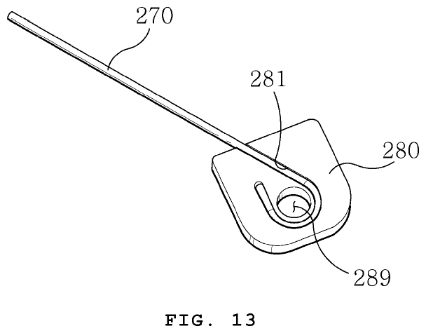

FIG. 13 is a schematic view showing the fixation member 280.

The fixing member 280 may have the insertion groove 281 into which the first end of the brush 270 is inserted and a first coupling hole 289 through which the coupling member 241 passes. Herein, the insertion groove 281 may have a shape of winding the first coupling hole 289 through which the coupling member 241 passes. When the fixing member 280 is inserted into the fixing groove 240, the first end of the brush 270 is inserted into the insertion groove 281, and the coupling member 241 is inserted into the first coupling hole 289, the first end of the brush 270 may have the shape of winding the coupling member 241. Therefore, the first end of the brush 270 catches on the coupling member 241, so that the brush 270 may be prevented from being separated from the fixing groove 240.

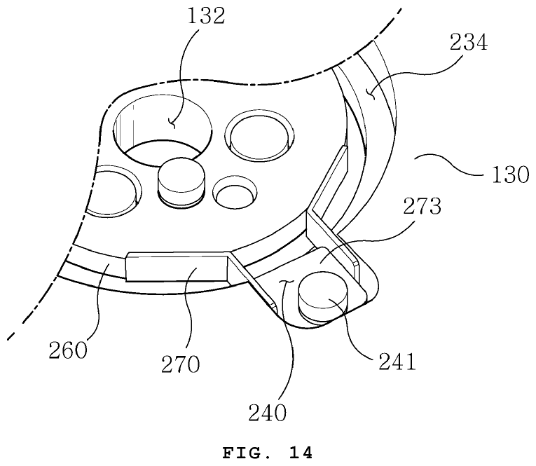

FIG. 14 is a perspective view showing the first electric channel according to a second embodiment.

The second end of the brush 270 in sliding-contact with the coupling means 260 is preferable extended in a rotating direction of the coupling means 260. As an example, when the coupling means 260 is rotated in a forward direction corresponding to clockwise, the second end of the brush 270 is preferably extended in a direction following the forward direction.

However, in this case, when the coupling means 260 is rotated in a reverse direction corresponding to counterclockwise, the second end of the brush 270 may be instantaneously spaced apart from the coupling means 260 by dapping thereof.

In order to allow the brush 270 to be securely in close contact with the coupling means 260 regardless of the rotating direction of the coupling means 260, the brush 270 may include a first brush 270 extended in the forward direction and a second brush 270 extended in the reverse direction.

Meanwhile, a method for excluding the separate fixing member 280 installed in the fixing groove 240 may be provided.

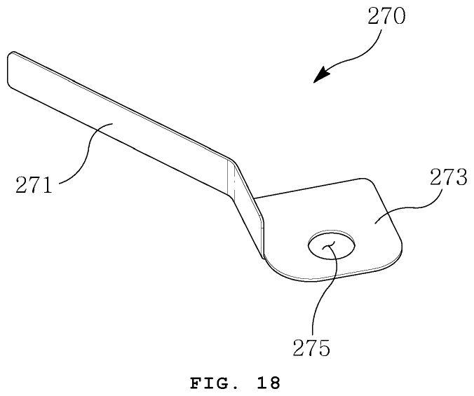

FIG. 18 is a schematic view showing the brush 270 of the present disclosure.

The first end of the brush 270 may include a plate-shaped fixing portion 273 inserted in the fixing groove 240. The fixing portion 273 may have the same shape and size as the fixing groove in a planar manner.

The fixing portion 273 may have a second coupling hole 275 in which the coupling member 241 is installed.

A body portion 271 is provided at one portion of the fixing portion 273 to be in contact with the coupling means 260. The body portion 271 may be extended from the one portion of the fixing portion 273 toward the coupling means 260. The body portion 271 may be bent perpendicular to the fixing portion 273 to be in linear or planar contact with the side surface of the coupling means 260.

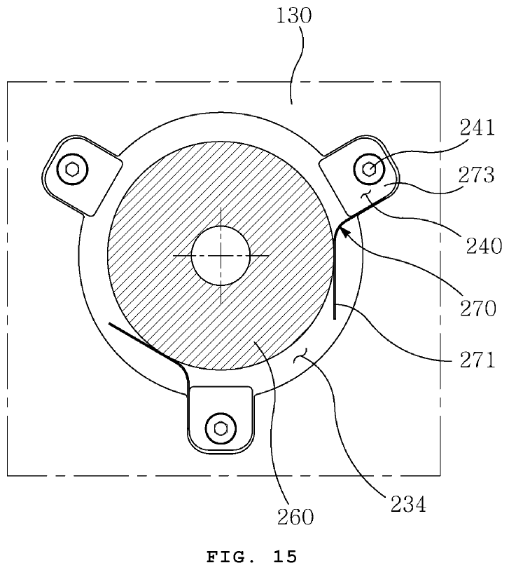

FIG. 15 is a plan view showing a state in which the brush 270 of the present disclosure is installed in the fixing groove 240.

When the fixing portion 273 is inserted into the fixing groove 240 and the coupling member 241 is installed in the second coupling hole 275, the fixing portion 273 corresponding to the first end of the brush 270 may be coupled to the fixing groove 240.

The body portion 271 protruding from the fixing groove 240 toward the coupling means 260 is bent in the forward direction or the reverse direction and may be elastically in close contact with the side surface of the coupling means 260.

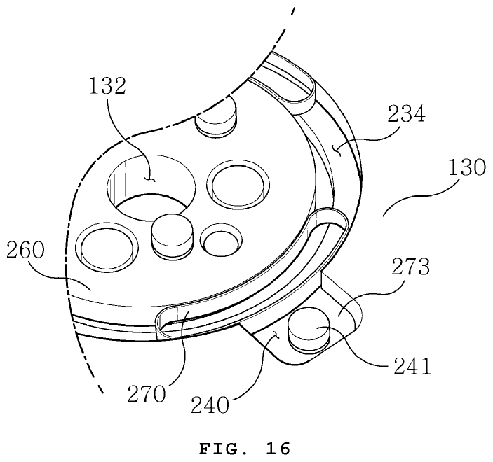

FIG. 16 is a perspective view showing the first electric channel according to a third embodiment.

The second end of the brush 270 configured to be brought into sliding-contact with the side surface of the coupling means 260 may be bent toward the inner wall of the coupling groove 234 to be rolled in a looped curve.

The second end of the brush 270 rolled in the looped curve may have elasticity such that a first portion thereof is in contact with the side surface of the coupling means 260 and a second portion thereof is in contact with the inner wall of the coupling groove 234.

The second end of the brush 270 rolled in the looped curve may be extended in the forward direction and the reverse direction based on the fixing groove 240.

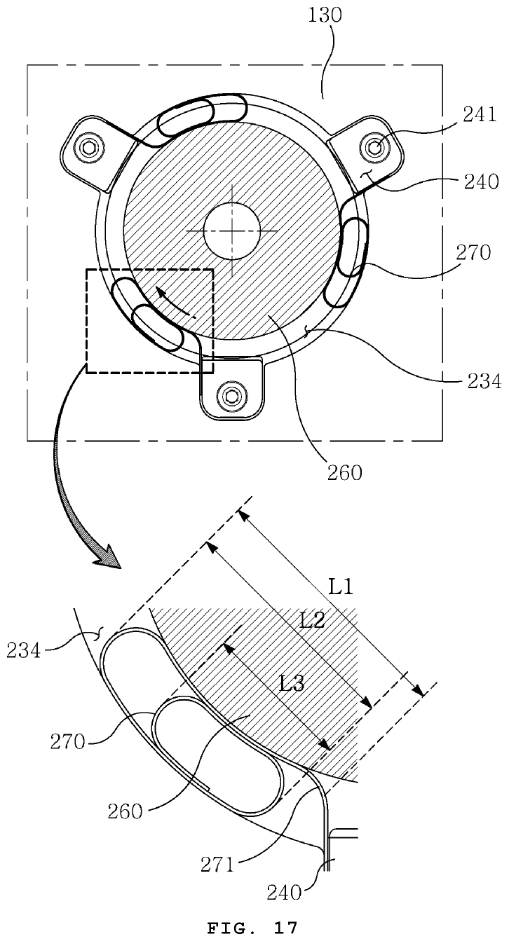

FIG. 17 is a plan view showing the first electric channel according to another third embodiment.

Even when the brush 270 with the second end of the looped curve is extended in one of the forward direction and the reverse direction, the brush may be securely in contact with the coupling means 260 regardless of the rotating direction of the coupling means 260.

The brush 270 formed in the looped curve may be in planar contact with the side surface of the coupling means 260 by the elasticity such that the first portion and the second portion thereof are respectively in contact with the side surface of the coupling means 260 and the inner wall of the coupling groove 234 at the same time. In order to the planar contact is uniformly maintained regardless of the rotating direction of the coupling means 260, the brush 270 may be formed as follows.

The brush 270 protruding from the fixing groove 240 may be extended in the forward direction by a first length L1 and may be in close contact with the side surface of the coupling means 260.

The brush 270 extended by the first length L1 may be bent toward the inner wall of the coupling groove 234 and then be extended in the reverse direction by a second length L2, and may be in close contact with the coupling groove 234.

The brush 270 extended by the second length L2 may be bent again toward the coupling means 260 and may be extended in the forward direction by a third length L3, and may be in close contact with the coupling means 260.

The brush 270 extended by the third length L3 may be bent toward the inner wall of the coupling groove 234 and then be extended in the reverse direction, and may be in close contact with the inner wall of the coupling groove 234.

According to the embodiment, the brush 270 is bent several times and layered, so that the elasticity of the brush 270 to be in close contact with the coupling means 260 and the inner wall of the coupling groove 234 may be strengthened. The strengthened elasticity may allow the brush 270 to be in planar contact with the coupling means 260 over a long section. Furthermore, even when the coupling means 260 is rotated in the reverse direction, the state where the brush 270 is rolled in the looped curve is maintained and thus electrical connection between the coupling means 260 and the disk part 130 may be maintained.

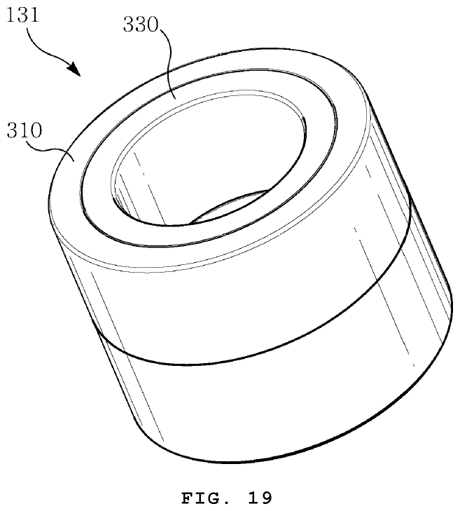

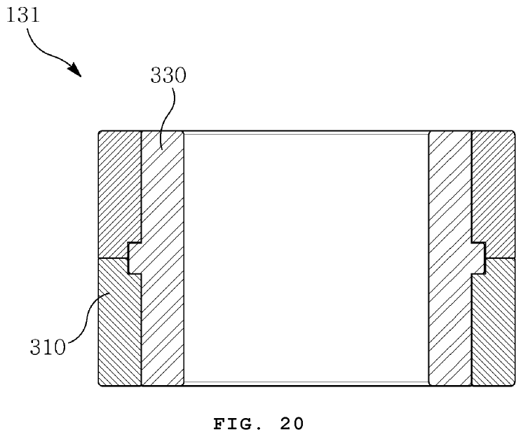

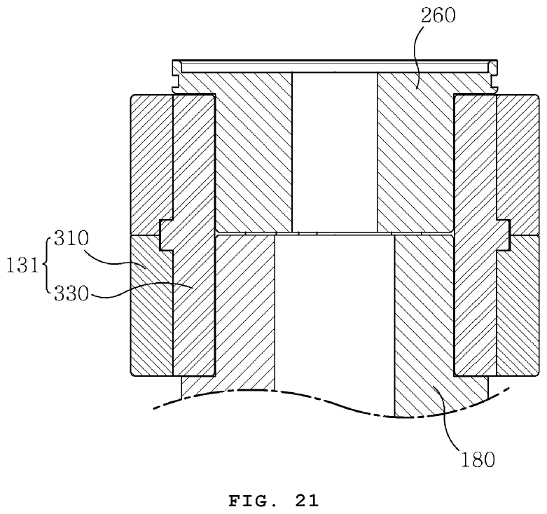

FIG. 19 is a perspective view showing a bearing. FIG. 20 is a sectional view showing the bearing. FIG. 21 is a sectional view showing a state in which the coupling means 260 and the pocket gear 180 are installed in the bearing.

The bearing corresponding to the bearing 131 may include the outer wheel 310 fixed to the first through hole 134, and the inner wheel 330 rotatably installed in the outer wheel 310.

In the sliding bearing such as the graphite bearing in which the inner wheel 330 is rotated with respect to the outer wheel 310 by sliding on a contact surface, the contact surface may be certainly provided between the outer wheel 310 and the inner wheel 330. Herein, the outer wheel 310 and the inner wheel 330 may include conductive materials, the bearing may electrically connect each element connected to the outer wheel 310 to each element connected to the inner wheel 330.

As an example, when the first through hole 134 to which the outer wheel 310 is securely installed is provided at the disk part 130, the outer wheel 310 may be electrically connected to both the first through hole 134 and the disk part 130.

The inner wheel 330 may be connected to the pocket part 150 through the coupling means 260, or may be connected to the pocket gear 180.

Since the pocket part 150 connected to the inner wheel 330 is electrically connected to the inner wheel 330, the pocket part 150 may be electrically connected to the disk part 130 through the inner wheel 330 and the outer wheel 310. In the above case, the second electric channel \textcircled{2} may be provided.

Alternately, when both the pocket part 150 and the pocket gear 180 are connected to the inner wheel 330, both the pocket part 150 and the pocket gear 180 may be electrically connected to each other through the inner wheel 330. In the above case, the third electric channel \textcircled{3} may be provided.

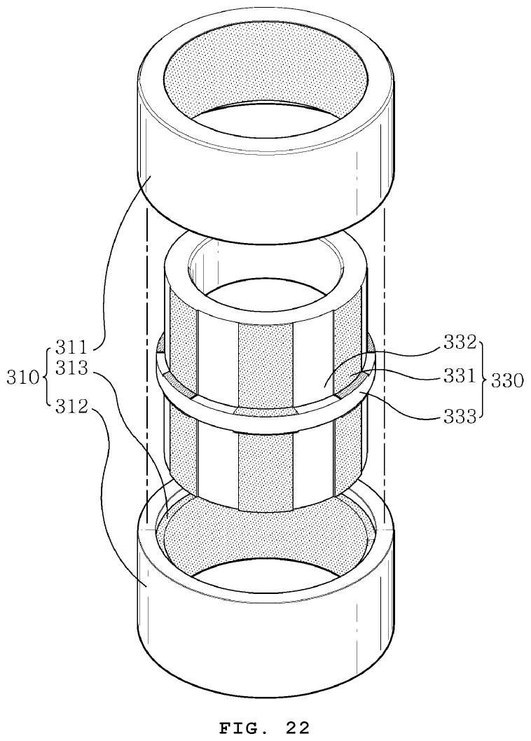

FIG. 22 is an exploded-perspective view showing the bearing.

A first sliding portion 313 may be formed on an inner circumferential surface of the outer wheel 310, and the first sliding portion 313 may have a groove shape in which a part of the inner wheel 330 is inserted.

In order to form the first sliding portion 313 sequentially along the inner circumference of the outer wheel, the outer wheel 310 may include a first outer wheel 311 and a second outer wheel 312 coupled to each other.

The first outer wheel 311 may have an upper portion of the first sliding portion 313, and the second outer wheel 312 may have a lower portion of a second sliding portion 333.

An outer circumferential surface 331 of the inner wheel 330 may have the second sliding portion 333 of a protrusion shape inserted in the first sliding portion 313.

In the outer circumferential surface 331 of the inner wheel 330, an engraving processing surface 332 may be provided for each preset angle, and the engraving processing surface 332 corresponds to a groove. The engraving processing surface 332 may reduce a friction load between the inner wheel 330 and the outer wheel 310.

The engraving processing surface 332 may be provided at an upper surface of the second sliding portion 333 facing the first outer wheel 311 or a lower surface of the second sliding portion 333 facing the second outer wheel 312.

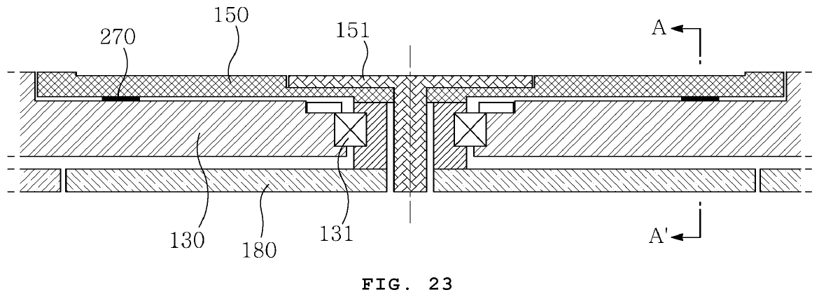

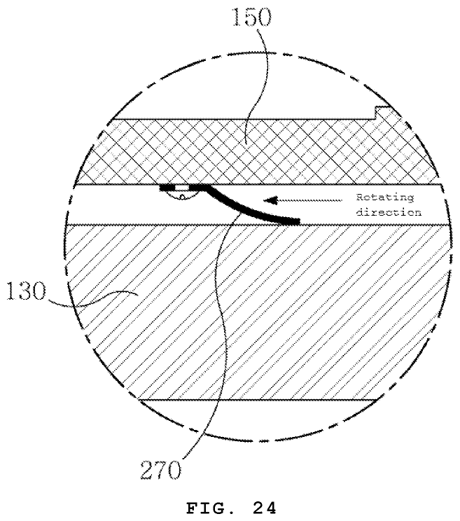

FIG. 23 is a schematic view showing the first electric channel according to a fourth embodiment. FIG. 24 is a schematic view showing a surface cut out along line A-A′ in FIG. 23.

The pocket part 150 of the present disclosure may be installed in the disk part 130 to be rotatably on its axis. The pocket part 150 may be spaced apart from the disk part 130, so that the pocket part 150 is not limited to be rotated on its axis.

In order to prevent particles on the pocket part 150 from being introduced into the gap between the pocket part 150 and the disk part 130, the bottom surface of the seating groove 138 of the disk part 130 facing the pocket part 150 or a second surface of the pocket part 150 facing the seating groove 138 may have a labyrinth seal.

The brush 270 may be installed at a fine gap between the lower surface of the pocket part 150 and the upper surface of the disk part 130.

The first end of the brush 270 may be coupled to any one of the lower surface of the pocket part 150 or the upper surface of the pocket part 150, and the second end of the brush 270 may be in sliding contact with a remaining one of the lower surface of the pocket part 150 or the upper surface of the pocket part 150.

The first end of the brush 270 may be preferably coupled to the pocket part 150 separable from the disk part 130 for the convenience of maintenance.

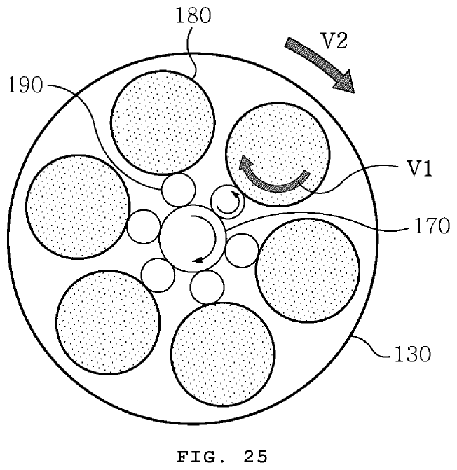

FIG. 25 is a schematic view showing the lower surface of the disk part 130.

The first rotating part may include the middle gear 190 between the main gear 170 and the pocket gear 180. Both the main gear 170 and the middle gear 190 may correspond to the link gear transmitting power of a motor to the pocket gear 180.

A first main gear 170, the pocket gear 180, and the pocket part 150 may be rotated in the same direction by the middle gear 190.

As an example, it is assumed that the main gear 170 is rotated clockwise in FIG. 25.

When the pocket gear 180 is directly engaged with the main gear 170, both the pocket gear 180 and the pocket part 150 may be rotated counterclockwise opposite to the rotating direction of the main gear 170.

However, when the middle gear 190 is disposed, both the pocket gear 180 and the pocket part 150 are also rotated clockwise.

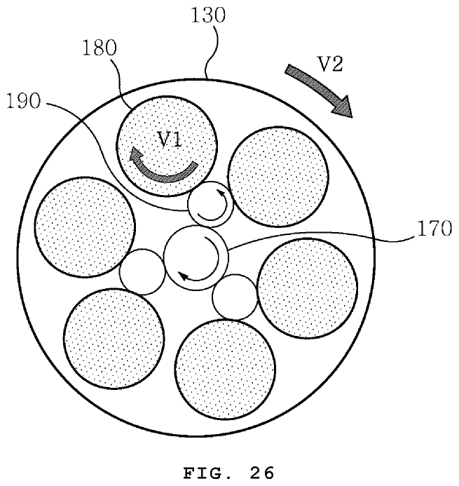

FIG. 26 is another schematic view showing the lower surface of the disk part 130.

A plurality of middle gears 190 may be provided to be suitable for the number of the pocket gears 180 as shown in FIG. 25. Herein, the number of the middle gears 190 that is necessary may be reduced by adjusting a diameter and an arrangement location of the middle gear 190.

As an example, one middle gear 190 may be configured to be engaged with two pocket gear 180 spaced apart from each other and with the first shaft 140. According to the embodiment, an even number of the pocket parts 150 is preferably installed at the disk part 130, and it is sufficient that the number of the middle gears 190 is half the number of the pocket parts 150.

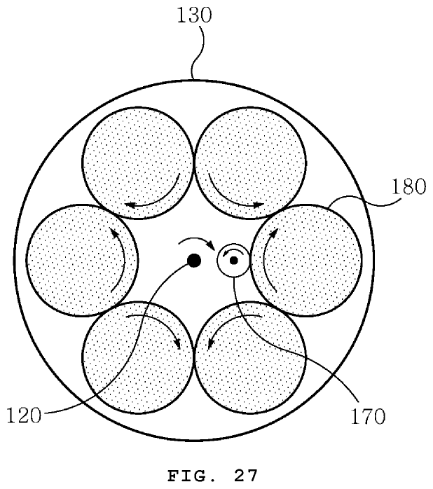

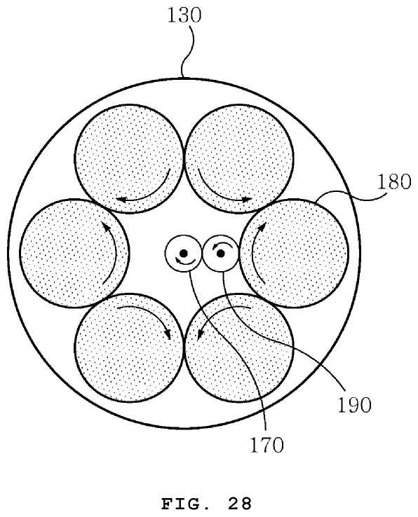

FIGS. 27 and 28 are another schematic views showing the lower surface of the disk part 130.

A plurality of pocket gears 180 may be engaged with each other. In the above case, when only any one of the pocket gears 180 is rotated by the motor, the entire pocket gears 180 may be rotated together.

The main gear 170 may be installed on the same axis as the second shaft 120, i.e., a rotating center of the disk part 130 or on a different axis from the second shaft 120.

In FIG. 27, the main gear 170 is formed at a different location from the second shaft 120. In FIG. 28, the main gear 170 may be formed on the same axis as the second shaft 120.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1-14. (canceled)

15: A substrate processing device comprising:
a disk part disposed in a chamber in which a heating unit is connected; and
a pocket part provided on a first surface of the disk part and on which a substrate is loaded,
wherein a heat hole is formed in a pocket part-installed surface of the disk part, so that heat generated by the heating unit passes through the heat hole.

16: The substrate processing device of claim 15, wherein the disk part is configured to be rotated with respect to the chamber,
any one substrate is exposed to at least one of source gas, purge gas, and reactant gas in response to rotation of the disk part, and
the pocket part on which the substrate is loaded is configured to be rotated separately from rotation of the disk part.

17: The substrate processing device of claim 15, wherein the heating unit comprises a heater;
the heater is provided on a second surface of the disk part in the chamber; and
the heat of the heater passes through the heat hole and then is transmitted to the pocket part.

18: The substrate processing device of claim 15, wherein the pocket part comprises a plurality of pocket parts on the disk part;
the heat hole is formed at each location facing each of the pocket parts;
the heating unit is provided at a location facing the heat hole; and
the heating unit and the disk part are configured to be relatively moved to each other, so that a plurality of heat holes alternately passes through a location facing a particular portion of the heating unit.

19: The substrate processing device of claim 15, wherein the first surface of the disk part has a seating groove on which the pocket part is seated;
the heat hole is formed on a middle portion of a bottom surface of the seating groove;
a diameter of the heat hole is formed smaller than a diameter of the pocket part; and
by a difference in diameter between the heat hole and the pocket part, a center portion of the pocket part faces the heat hole and an edge of the pocket part is rotatably supported by an edge of the bottom surface of the seating groove.

20: The substrate processing device of claim 15, wherein an installation portion formed on a middle portion of the heat hole and a connection portion arranged to cross the heat hole to connect the installation portion to the disk part are provided;
the installation portion comprises a bearing serving as a rotating center of the pocket part; and
the pocket part is provided on the disk part to be rotatable on the bearing with respect to the disk part.

21: The substrate processing device of claim 15, wherein an installation portion formed on a middle portion of the heat hole and a connection portion arranged to cross the heat hole to connect the installation portion to the disk part are provided;
the connection portion comprises a plurality of connection portions;
each of the connection portions has a rod shape, and the connection portions are arranged at different angles with the installation portion as the center;
the heat hole is divided into a plurality of heat holes by the plurality of the connection portions; and
each of the divided heat holes of the heat hole has a fan shape.

22: The substrate processing device of claim 15, wherein a lift portion is provided at a middle portion of the pocket part to raise and lower the substrate; and
a lift hole is provided so that a lift drive part pushing up or pulling down the lift portion passes through the lift hole.

23: The substrate processing device of claim 15, wherein an end cap provided at a second surface of the disk part and configured to block at least a part of the heat hole is provided.

24: The substrate processing device of claim 15, wherein a pocket gear installed at a second surface of the disk part and connected to the pocket part, a link gear engaged with the pocket gear, and a first drive part configured to rotate the link gear;
when the link gear is rotated by the first drive part, the pocket part is rotated together with the pocket gear engaged with the link gear; and
the link gear is arranged at a different location from the pocket gear on a direction parallel to the disk part.

25: The substrate processing device of claim 15, wherein a bearing is connected to the pocket part and configured to be rotatably supported by the disk part;
a pocket gear connected to the pocket part has a center portion removably coupled to the bearing;
a lift portion is provided at a middle portion of the pocket part to raise and lower the substrate;
a lift hole is formed on a middle portion of the bearing so that a lift drive part pushing up or pulling down the lift portion passes through the lift hole;
a through hole is formed on a middle portion of the center portion so that the lift portion passes through the through hole; and
the lift hole and the through hole are formed coaxially.

26: The substrate processing device of claim 15, wherein a bearing connected to the pocket part, and a pocket gear installed on a second surface of the disk part and configured to rotate the bearing are provided;
the pocket part is grounded to a ground terminal through at least one of a first electric channel, a second electric channel, and a third electric channel through which electricity communicates;
when the conductive disk part electrically connected to the ground terminal is provided, the first electric channel is an electric channel configured to electrically connect the pocket part to the disk part by using a brush part in contact with both the pocket part and the disk part;
when the conductive disk part electrically connected to the ground terminal is provided, the second electric channel is an electric channel configured to electrically connect the pocket part to the disk part by the bearing; and
when the pocket gear electrically connected to the ground terminal is provided, the third electric channel is an electric channel configured to electrically connect the pocket part to the pocket gear by the bearing.

27: The substrate processing device of claim 15, wherein a bearing connected to the pocket part, an installation portion formed in a middle portion of the heat hole, and a connection portion arranged to cross the heat hole to connect the installation portion to the disk part are provided;
a first surface of the installation portion facing the pocket part has a coupling groove into which a coupling unit provided at the pocket part is inserted;
a first through hole is formed in a middle portion of a bottom surface of the coupling groove, and the first through hole has a diameter smaller than a diameter of the coupling groove and into which the bearing is inserted;
the coupling unit inserted in the coupling groove is connected to the bearing so as to be rotated together with the bearing;
the diameter of the coupling groove is larger than a diameter of the coupling unit;
a brush is disposed between an inner wall of the coupling groove and a side surface of the coupling unit;
a first end of the brush is fixed to the disk part or the side surface of the coupling unit; and
a second end of the brush is brought into sliding-contact with the disk part or the coupling unit.

28: The substrate processing device of claim 15, wherein an installation portion provided at a middle portion of the heat hole, a coupling unit provided at the pocket part, and a coupling groove into which the coupling unit is inserted are provided;
a brush in sliding contact with a side surface of the coupling unit is rolled in a looped curve shape by being bent toward an inner wall of the coupling groove; and
a first end of the brush rolled in the looped curve shape is elastically in contact with the side surface of the coupling unit, and a second end of the brush is elastically in contact with the inner wall of the coupling groove.

29: A substrate processing device comprising:
a disk part disposed in a chamber in which a heating unit is connected; and
a pocket part provided on a first surface of the disk part and on which a substrate is loaded,
wherein a pocket gear is provided to face the disk part, and
a gear hole through which heat of the heating unit passes is formed in the pocket gear.

30: The substrate processing device of claim 29, wherein the disk part is rotated with respect to the chamber;
any one substrate is exposed to at least one of source gas, purge gas, and reactant gas in response to rotation of the disk part; and
the pocket part on which the substrate is loaded is rotated separately from rotation of the disk part.

31: The substrate processing device of claim 29, wherein a heat hole is formed in the disk part so that the heat generated by the heating unit passes through the heat hole;
the pocket gear is formed in a size capable of covering the heat hole; and
the gear hole is formed in the pocket gear facing the heat hole.

32: The substrate processing device of claim 29, wherein a heat hole is formed in the disk part so that the heat generated by the heating unit passes through the heat hole;
a bearing is connected to the pocket part;
the bearing is rotatably supported by the disk part;
the pocket gear comprises a ring portion having a ring shape, a center portion removably coupled to the bearing, and a connection portion arranged to cross the gear hole to connect the ring portion to the center portion;
when the pocket gear is rotated, the connection portion periodically blocks the heat hole;
the pocket gear comprises a plurality types of pocket gears of which at least one of a formation location, the number, an area, and a shape of the connection portion is different from each other; and
the plurality types of the pocket gears are configured to be replaced with respect to the bearing so as to adjust amount of the heat passing through the heat hole.

33: A substrate processing device comprising:
a disk part disposed in a chamber in which a heating unit is connected;
a pocket part provided on a first surface of the disk part and on which a substrate is loaded;
a high-frequency power supply configured to generate plasma;
an upper electrode or an antenna connected to a first end of the high-frequency power supply; and
a lower electrode or a ground terminal connected to a second end of the high-frequency power supply,
wherein the pocket part is connected to the lower electrode or the ground terminal;
the pocket part is rotatably provided with respect to the disk part; and
an electrical connection unit configured to electrically connect the lower electrode or the ground terminal that is a fixed portion to the pocket part that is a rotated portion.

34: The substrate processing device of claim 33, wherein the electrical connection unit comprises a brush elastically in contact with the pocket part.
